(19) United States
(12) Patent Application Publication
(10) Pub. No.: US 2019/0327002 A1
(43) Pub. Date: Oct. 24, 2019

(54) ISOLATION DEVICE, ISOLATION SENSOR PACKAGE, AND METHOD

(71) Applicant: AVAGO TECHNOLOGIES GENERAL IP (SINGAPORE) PTE. LTD., Singapore (SG)

(72) Inventors: Huey Chian Foong, Singapore (SG); Richard Lum, Singapore (SG); Gek Yong Ng, Singapore (SG)

(21) Appl. No.: 15/959,384

(22) Filed: Apr. 23, 2018

(51) Int. Cl. H04B 10/80; H04B 10/69; G11C 7/06; H04L 25/06

(52) U.S. Cl. CPC H04B 10/802; H04B 10/695; H04L 25/063; H04B 10/697; G11C 7/06; H04B 10/6933

(57) ABSTRACT

An example of an isolation sensor package is disclosed to include a first Integrated Circuit (IC) chip and a second IC chip. The first IC chip may include an input interface circuit that receives an input signal from a first input signal terminal and a second input signal terminal, where the input signal ranges between a first positive voltage and a first negative voltage. The first IC chip may further include a negative voltage generator that generates a second negative voltage, a level shifter that receives an output of the input interface circuit and generates a modified signal having a voltage level between a ground voltage provided to the ground terminal and a second positive voltage that is present at a voltage supply terminal. The first IC chip may further produce a signal based on the modified signal generated by the level shifter.

### FIELD OF THE DISCLOSURE

The present disclosure is generally directed toward electronic isolation and devices for accommodating the same.

### BACKGROUND

A galvanic isolator provides a way for transmitting a signal from one electrical circuit to another electrical circuit in a control system when the two electrical circuits may otherwise be electrically isolated from one another. Usually the two electrical circuits operate at different voltages, and thus, are electrically isolated. For example, consider an application in which a 5V battery powered controller board is configured to control a motor circuit operating at 240V. In this example, the 240V motor circuit may be electrically isolated from the 5V controller circuit, while permitting the 5V controller circuit to send or receive signals from the 240V motor circuit. In another example involving a solid-state lighting system, a 240V Alternate Current (AC) power supply may be converted to two different Direct Current (DC) power domains. The two DC power domains are electrically isolated as there is no direct current path between the two DC domains, but there may be signals that need to be communicated between the two power domains. In these applications, an isolator may be used to provide voltage and/or noise isolation while still permitting signaling and/or information exchange between the two circuit systems.

Most optically-isolated voltage sensors have an input range that is above ground and a single supply voltage. This means that most optically-isolated voltage sensors cannot be used for AC voltage sensing applications. Although some optically-isolated current sensors have an input range that extends slightly below ground (e.g., +/−0.32V), the input impedance of such sensors are not large enough for voltage sensing.

The unfortunate byproduct is that isolated sensors with limited input voltage ranges can only detect unipolar signals or slightly negative signals (e.g., less than −0.2V). External components which are not integrated into the IC chip or silicon of the sensor are needed to sense bipolar, wide-swing signals. Furthermore, large input signals will cause distortion, meaning that the approach of using an optical sensor as a voltage sensor is only suitable for small input voltage ranges. While the use of external components such as preamplifiers, level shifters, and negative voltage generators are possible outside of the IC, these external components will introduce noise to the system due to cross-talk and coupling on the Printed Circuit Board (PCB), which effectively impacts the signal-to-noise ratio (SNR) of the sensor.

### BRIEF DESCRIPTION OF THE DRAWINGS

The present disclosure is described in conjunction with the appended figures, which are not necessarily drawn to scale:

FIG. 1 illustrates a first example sensor package in accordance with at least some embodiments of the present disclosure;

FIG. 2 illustrates a second example sensor package in accordance with at least some embodiments of the present disclosure;

FIG. 3 illustrates a third example sensor package in accordance with at least some embodiments of the present disclosure;

FIG. 4 illustrates a fourth example sensor package in accordance with at least some embodiments of the present disclosure;

FIG. 5 illustrates an example set of functional circuit components in accordance with at least some embodiments of the present disclosure;

FIG. 6 is a flow chart depicting a method of operating one or more circuits in a sensor package in accordance with at least some embodiments of the present disclosure;

FIG. 7 illustrates a first example offset cancellation circuit in accordance with at least some embodiments of the present disclosure;

FIG. 8 is a flow diagram depicting another method of operating one or more circuits in a sensor package in accordance with at least some embodiments of the present disclosure;

FIG. 9 is a flow diagram depicting yet another method of operating one or more circuits in a sensor package in accordance with at least some embodiments of the present disclosure;

FIG. 10 illustrates a second example offset cancellation circuit in accordance with at least some embodiments of the present disclosure;

FIG. 11 illustrates details of an example preamplifier with a level shifter in accordance with at least some embodiments of the present disclosure;

FIG. 12 illustrates a third example offset cancellation circuit in accordance with at least some embodiments of the present disclosure;

FIG. 13 illustrates a fourth example offset cancellation circuit in accordance with at least some embodiments of the present disclosure;

FIG. 14 illustrates a fifth example offset cancellation circuit in accordance with at least some embodiments of the present disclosure;

FIG. 15 illustrates a sixth example offset cancellation circuit in accordance with at least some embodiments of the present disclosure;

FIG. 16 illustrates a first example translinear offset cancellation circuit in accordance with at least some embodiments of the present disclosure;

FIG. 17 illustrates a second example translinear offset cancellation circuit in accordance with at least some embodiments of the present disclosure;

FIG. 18 illustrates input and output waveforms of a conditioner circuit in accordance with at least some embodiments of the present disclosure;

FIG. 19 illustrates an example of a main charge pump circuit in accordance with at least some embodiments of the present disclosure;

FIG. 20 illustrates an example of a non-overlapping clock generation circuit in accordance with at least some embodiments of the present disclosure;

FIG. 21 illustrates a first auxiliary charge pump circuit in accordance with at least some embodiments of the present disclosure;

FIG. 22 illustrates a second auxiliary charge pump circuit in accordance with at least some embodiments of the present disclosure;

FIG. 23 illustrates a low-drop-out regulator circuit in accordance with at least some embodiments of the present disclosure; and

FIG. 24 illustrates a shunt circuit in accordance with at least some embodiments of the present disclosure.

### DETAILED DESCRIPTION

The ensuing description provides embodiments only, and is not intended to limit the scope, applicability, or configuration of the claims. Rather, the ensuing description will provide those skilled in the art with an enabling description for implementing the described embodiments. It being understood that various changes may be made in the function and arrangement of elements without departing from the spirit and scope of the appended claims.

Various aspects of the present disclosure will be described herein with reference to drawings that are schematic illustrations of idealized configurations. As such, variations from the shapes of the illustrations as a result, for example, manufacturing techniques and/or tolerances, are to be expected. Thus, the various aspects of the present disclosure presented throughout this document should not be construed as limited to the particular shapes of elements (e.g., regions, layers, sections, substrates, etc.) illustrated and described herein but are to include deviations in shapes that result, for example, from manufacturing. By way of example, an element illustrated or described as a rectangle may have rounded or curved features and/or a gradient concentration at its edges rather than a discrete change from one element to another. Thus, the elements illustrated in the drawings are schematic in nature and their shapes are not intended to illustrate the precise shape of an element and are not intended to limit the scope of the present disclosure.

It will be understood that when an element such as a region, layer, section, substrate, or the like, is referred to as being “on” another element, it can be directly on the other element or intervening elements may also be present. In contrast, when an element is referred to as being “directly on” another element, there are no intervening elements present. It will be further understood that when an element is referred to as being “formed” or “established” on another element, it can be grown, deposited, etched, attached, connected, coupled, or otherwise prepared or fabricated on the other element or an intervening element.

Furthermore, relative terms, such as “lower” or “bottom” and “upper” or “top” may be used herein to describe one element's relationship to another element as illustrated in the drawings. It will be understood that relative terms are intended to encompass different orientations of an apparatus in addition to the orientation depicted in the drawings. By way of example, if an apparatus in the drawings is turned over, elements described as being on the “lower” side of other elements would then be oriented on the “upper” side of the other elements. The term “lower” can, therefore, encompass both an orientation of “lower” and “upper” depending of the particular orientation of the apparatus. Similarly, if an apparatus in the drawing is turned over, elements described as “below” or “beneath” other elements would then be oriented “above” the other elements. The terms “below” or “beneath” can therefore encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and this disclosure.

As used herein, the singular forms “a,” “an,” and “the” are intended to include the plural forms as well, unless the context clearly indicates otherwise. It will be further understood that the terms “comprise,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

It should be appreciated that any of the circuit elements or configurations of circuit elements depicted and described herein may be replaced or modified with other circuit elements to achieve the functional capabilities of those circuits. The claims should not be considered to be limited to any particular configuration or use of circuit elements.

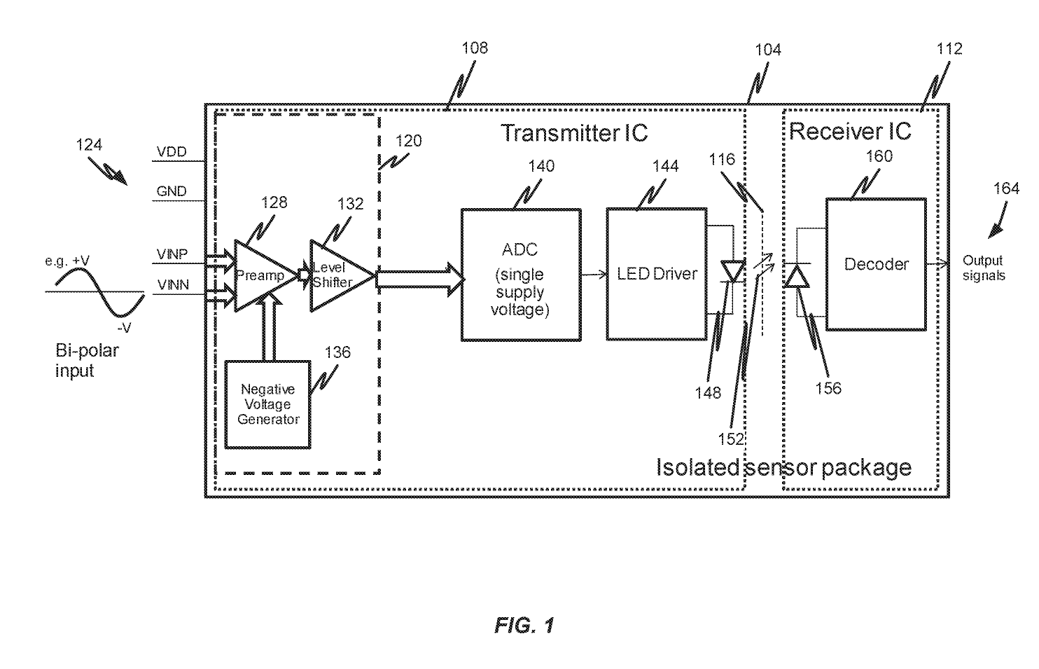

Referring now to FIGS. 1-24, various configurations of isolation systems, isolators, isolation devices, isolated sensor packages, and circuit elements of the same will be described. In some embodiments, the isolators described herein may be incorporated into any system which requires current and/or voltage monitoring, but is susceptible to transients. In some embodiments, the isolation system in which an isolator described herein is rated to operate at about 5 kV, 10 kV, or more. Stated another way, the input side (e.g., a high-voltage side) of the isolator or isolation system may be directly connected to a 5 kV, 10 kV, 15 kV or greater source without damaging the isolator or any electronic devices attached to the output side (e.g., a low-voltage side) of the isolator. Accordingly, an isolation system which employs one or more of the isolators disclosed herein may be configured to operate in high-voltage or high-current systems but may also be configured to separate the high-voltage or high-current systems from a low-voltage or low-current system.

In some embodiments, an isolation device and isolated sensor package are described that utilize a negative voltage generator to generate a negative voltage for the supply rail of an input stage of an input interface circuit. In some embodiments, only a single supply is needed. By increasing the headroom of the input stage, embodiments of the present disclosure enable the sensed signal to go negative without affecting linearity.

Embodiments disclosed herein may also incorporate one or more analog voltage shifters to convert the signal range from bipolar (plus and minus with reference to ground) to unipolar (above ground) at the output. The linearity and harmonic distortion of the analog voltage shifters can be improved by placing them inside the feedback loop of the input interface circuit, thus achieving optimization in the signal path.

Embodiments disclosed herein further provide a low noise offset cancellation circuit by linear offset trimming, which includes a translinear circuit that controls the gates of a pair of transistors to steer a common current to the two current sources of the analog voltage shifters thereby cancelling the offset error of the input interface circuit. As the source current is common, its noise effect is cancelled at the output of the input interface circuit. The translinear circuit may help to achieve linear trimming from a single programmable current source. This can be contrasted to nonlinear trimming techniques or trimming two different currents, which have noise effect at the output. The programmable source can be driven by a current DAC (digital-to-analog converter) with input controlled by trimming cells.

In some embodiments, an isolation device is provided that electrically isolates a first circuit from a second circuit, where the isolation device includes:

an input interface circuit configured to receive an input signal from the first circuit to produce a first output signal, wherein the input signal ranges between a first negative voltage and a first positive voltage;

a supply voltage terminal configured to provide a second positive voltage;

a ground terminal configured to provide a ground voltage;

a negative voltage generator configured to generate a second negative voltage for the input interface circuit;

a level shifter configured to shift the first output signal into a second output signal having a voltage level between the ground voltage and the second positive voltage;

an analog-to-digital circuit configured to convert the second output signal into a bit stream signal;

an emitter configured to convert the bit stream signal into an optical signal;

a detector configured to receive the optical signal and then generate a reproduced signal based on the received optical signal; and

an isolation boundary positioned between the detector and the emitter thereby providing the isolation between the first circuit and the second circuit, wherein the ground voltage and the second positive voltage are fed to the level shifter, the analog-to-digital circuit, and the emitter.

With reference now to FIG. 1, a first example of an isolated sensor package 104 will be described in accordance with at least some embodiments of the present disclosure. The isolated sensor package 104 may include a transmitter Integrated Circuit (IC) 108 and receiver IC 112 separated from one another by an isolation boundary 116. The transmitter IC 108 and receiver IC 112 may both be part of the isolated sensor package 104, meaning that both ICs are potted in a common encapsulant or otherwise housed together within a common device housing. The isolation boundary 116 provides a mechanism for electrically isolating the transmitter IC 108 from the receiver IC 112. As a non-limiting example, the transmitter IC 108 may be connected to a first circuit via a plurality of input terminals 124 whereas the receiver IC 112 is connected to a second circuit via one or more output terminals 164. The first circuit to which the transmitter IC 108 is connected may be operating at a first voltage (e.g., in a high voltage environment, such as at least 10 kV) whereas the second circuit to which the receiver IC 112 is connected may be operated at a second voltage (e.g., in a low voltage environment, such as no more than 10V). The isolation boundary 116 prevents electrical current from flowing between the first circuit and second circuit. Any type of known electrically-insulative material may be used within the isolated sensor package 104 to electrically separate the transmitter IC 108 from the receiver IC 112. As some non-limiting examples, the isolation boundary 116 may correspond to a predetermined amount of space between electrically-conductive portions of the transmitter IC 108 and receiver IC 112. The space may further be filled with non-conductive materials such as glass or a polymer, for example.

The electrically-insulative material of the isolation boundary 116 may substantially prevent electrical current from flowing between the ICs 108, 112, but the isolation boundary 116 may still allow a signal 152 to pass from the transmitter IC 108 to the receiver IC 112. As a non-limiting example, the isolation boundary 116 may allow light of a predetermined wavelength to pass therethrough, thereby enabling the transmitter IC 108 to communicate the signal 152 to the receiver IC 112 in the form of emitted light. The signal 152, in such an embodiment facilitates the communication of information from the transmitter IC 108 to the receiver IC 112 without allowing electrical current to pass between the ICs 108, 112. The signal 152 may represent an electrical signal generated in the transmitter IC 108, which may correspond to a representation of an input signal received at one or more of the input terminals 124. As will be discussed in further detail herein, the transmitter IC 108 may be provided with a plurality of circuit components that help condition an input signal received at the input terminals 124 into a signal that is transmitted to the receiver IC 112 in the form of the signal 152 (e.g., as emitted light). The receiver IC 112 may also contain a plurality of circuit components that enable the receiver IC 112 to convert the signal 152 back into an electrical signal that can be communicated to the second circuit via the one or more output terminals 164.

The transmitter IC 108 is shown to include an input interface circuit 128, a level shifter 132, a negative voltage generator 136, an Analog-to-Digital Converter (ADC) circuit 140, a driver circuit 144, and an emitter 148. The receiver IC 112 is shown to include a detector 156 and a decoder circuit 160. Although the components of the ICs 108, 112 are shown to communicate with one another via emitted light as the signal 152, it should be appreciated that any type of non-electrical phenomenon can be used to create the signal 152. Furthermore, the signal 152 may correspond to a control signal to be communicated from the first circuit to the second circuit (operating in a different voltage domain), a feedback signal, a measured voltage in the first circuit, a measured current in the first circuit, or any other information that is shared between the transmitter IC 108 and receiver IC 112.

The transmitter IC 108 is shown to be electrically connected to a bi-polar input via terminals VINP and VINN, which carry the positive and negative portions of the bi-polar input signal, respectively. In some embodiments, the input signal corresponds to an AC signal that fluctuates between a first positive voltage and a first negative voltage. The bi-polar input may, therefore, have a particular frequency and may cross a ground (GND) or reference voltage (e.g., a zero voltage) at regular intervals. The magnitude of the first positive voltage may or may not be the same as the magnitude of the first negative voltage.

The transmitter IC 108 is also shown to be connected to a GND terminal and another supply voltage terminal VDD. The GND terminal may be used to connect the transmitter IC 108 to ground or some other reference voltage that is at or near zero (or some other preferred/determined reference voltage). The supply voltage terminal may be configured to receive a second positive voltage, where the second positive voltage is different from the first positive voltage. In some embodiments, magnitude of the second positive voltage is larger than a magnitude of the first positive voltage.

Although the isolated sensor package 104 is shown to have four input terminals 124, it should be appreciated that the package 104 may be provided with a greater or lesser number of input terminals without departing from the scope of the present disclosure. Moreover, one or more of the input terminals 124 of the isolated sensor package 104 may not necessarily be connected to or carry an electrical signal to components of the transmitter IC 108. Said another way, the package 104 may have other components that are not depicted and which may not necessarily be part of a transmitter IC 108.

The input interface circuit 128 is shown to receive the bi-polar input signal by virtue of its connection to the input terminals VINP, VINN. As noted above, the input signal may range between the first negative voltage and the first positive voltage that are natively part of the bi-polar input signal. As will be discussed in further detail herein, the input interface circuit 128 may comprise a number of circuit elements that enable the input interface circuit 128 to produce a first output signal that is provided to the level shifter 132. The input interface circuit 128 may produce the first output signal with the assistance of an input provided by the negative voltage generator 136.

In some embodiments, the negative voltage generator 136 provides the input interface circuit 128 with a second negative voltage to help drive certain components within the input interface circuit 128. The second negative voltage produced by the negative voltage generator 136 may be less than or equal to the first negative voltage received at the input terminal VINN. In some embodiments, the magnitude of the second negative voltage is greater than the magnitude of the first negative voltage. The negative voltage generator 136 may provide the second negative voltage as its output for consumption by the input interface circuit 128.

The output of the input interface circuit 128 is provided to the level shifter 132, which is configured to shift the output of the input interface circuit 128 into a second output signal for consumption by the ADC circuit 140. In some embodiments, the output of the level shifter 132 exhibits a voltage level between the ground voltage and the second positive voltage. Thus, the output of the level shifter 132 is no longer crossing a ground or reference voltage. Rather, the level shifter 132 has shifted the bi-polar input above ground to fluctuate between ground and the second positive voltage provided at the supply voltage terminal VDD. This shifting of the bi-polar input helps to create a signal 152 that is transmittable across the isolation boundary 116 with a suitable SNR.

In accordance with at least some embodiments of the present disclosure, the input interface circuit 128, the level shifter 132, and the negative voltage generator 136 may all be considered part of conditioner circuitry 120 within the transmitter IC 108. The input interface circuit 128 may receive the input signal via terminals VINP, VINN, but may be driven or otherwise fed voltage inputs from the supply voltage terminal VDD and ground terminal GND. As discussed above, the input interface circuit 128 also receives a second negative voltage input from the negative voltage generator 136. Thus, the input interface circuit 128 may be configured to be driven between the second positive voltage (provided by the supply voltage terminal VDD) and the second negative voltage provided by the negative voltage generator 136. One or more components of the input interface circuit 128 may also be connected to a ground voltage provided by the ground terminal GND. The negative voltage generator 136 and level shifter may also be driven between the second positive voltage (provided by the supply voltage terminal VDD) and the ground voltage provided by the ground terminal GND. This utilization of a common reference voltage and supply voltage for all components in the conditioner circuitry 120 as well as the other components of the transmitter IC 108 helps to reduce the overall noise provided to the system and helps to ensure that a quality representation of the bi-polar input signal is shared with the receiver IC 112 via the signal 152. Although the conditioner circuitry 120 is shown to include the input interface circuit 128, level shifter 132, and negative voltage generator 136, it should be appreciated that the conditioner circuitry 120 may include a greater or lesser number of circuits without departing from the scope of the present disclosure.

The ADC circuit 140 is shown to receive the output of the level shifter 132 at its input. The ADC circuit 140 may be configured to operate between the ground or reference voltage provided at the ground terminal GND and the second positive voltage provided at the supply voltage terminal VDD. The ADC circuit 140 may be configured to receive the output of the level shifter 132 and produce a bit stream signal that is representative of the analog version of the output of the level shifter 132. Because the output of the level shifter 132 fluctuates between the ground voltage and the second positive voltage, the ADC circuit 140 is able to produce a bit stream signal that suitably represents the input received at the ADC circuit 140.

The bit stream signal produced by the ADC circuit 140 is provided to the driver circuit 144. The driver circuit 144 uses the bit stream signal to drive the emitter 148 to produce the signal 152 as a non-electrical representation of the bit stream signal. In some embodiments, the driver 144 corresponds to a Light Emitting Diode (LED) driver when the emitter 148 corresponds to an LED or similar type of light-emitting device (e.g., a laser, Vertical-Cavity Surface-Emitting Laser (VCSEL), array of LEDs, etc.). Like the ADC circuit 140, the driver 144 is connected to (e.g., driven by) the ground voltage provided at the ground terminal GND and the second positive voltage provided at the supply voltage terminal VDD. Thus, all components of the transmitter IC 108 may be driven by a common positive voltage (e.g., the second positive voltage at the supply voltage terminal VDD) and may share a reference to the common ground voltage provided at the ground terminal GND. This helps to reduce voltage mismatches and noise issues that would be present if one or more components of the conditioner circuitry 120 were provided outside the transmitter IC 108.

The signal 152 produced by the emitter 148 is received at the detector 156 and re-converted back into an electrical signal, which is fed to the decoder 160. In some embodiments, the electrical signal output by the detector 156 contains the data provided in the bit stream signal output by the ADC circuit 140, but is provided at a different voltage due to the electrical isolation between ICs 108, 112. The decoder 160 may contain one or more components that condition the output of the detector 156 for transmission on the output terminal(s) 164. In some embodiments, the decoder 160 includes one or more amplifiers, transistors, etc. that facilitate the production of an output signal that substantially represents the bi-polar input signal received by the transmitter IC 108. As discussed above, the receiver IC 112 may be electrically isolated from the transmitter IC 108. Accordingly, the power supply and ground voltages provided to the receiver IC 112 may be independent from the power supply and ground voltages provided to the transmitter IC 108. The output signal is fed to a second circuit that is electrically isolated from the first circuit, to which the transmitter IC 108 is connected.

While the transmitter IC 108 and receiver IC 112 have been depicted and described as individual IC elements, it should be appreciated that embodiments of the present disclosure are not so limited. The transmitter IC 108 and/or receiver IC 112 may be provided as individual IC chips or a collection of IC chips (e.g., two or more discrete IC chips).

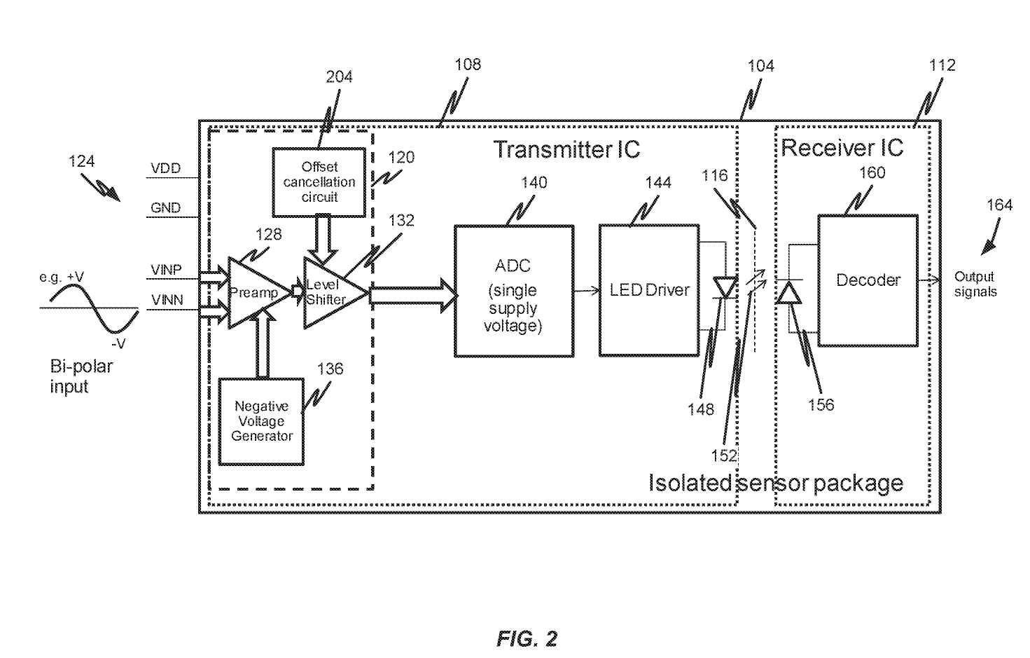

With reference now to FIG. 2, an alternative configuration of the isolated sensor package 104 will be described in accordance with at least some embodiments of the present disclosure. The isolated sensor package 104 in this example is shown as being similar to the example of FIG. 1, except that the transmitter IC 108 further includes an offset cancellation circuit 204. The offset cancellation circuit 204 is shown to provide an output to the level shifter 132. In some embodiments, the offset cancellation circuit 204 may be driven by the ground voltage provided at the ground terminal GND and the second positive voltage provided at the supply voltage terminal VDD. In other words, the offset cancellation circuit 204 may be operated by the same ground and second positive voltage that are used to operate the level shifter 132, negative voltage generator 136, ADC circuit 140, and driver 144.

The output of the offset cancellation circuit 204 may correspond to an input signal for the level shifter 132. The offset output provided by the offset cancellation circuit 204 may be as low as a few microvolts. The offset output may be dynamically adjustable or may correspond to a single, constant voltage that is provided by a One-Time Programmable (OTP) cell contained within the offset cancellation circuit 204. The offset cancellation circuit 204 may be provided to mitigate an offset that arises between the input interface circuit 128 and the level shifter 132. Said another way, in the event that there is an offset between the input interface circuit 128 and the level shifter 132, the offset cancellation circuit 204 is configured to adjust the operation of the level shifter 132 to accommodate the offset.

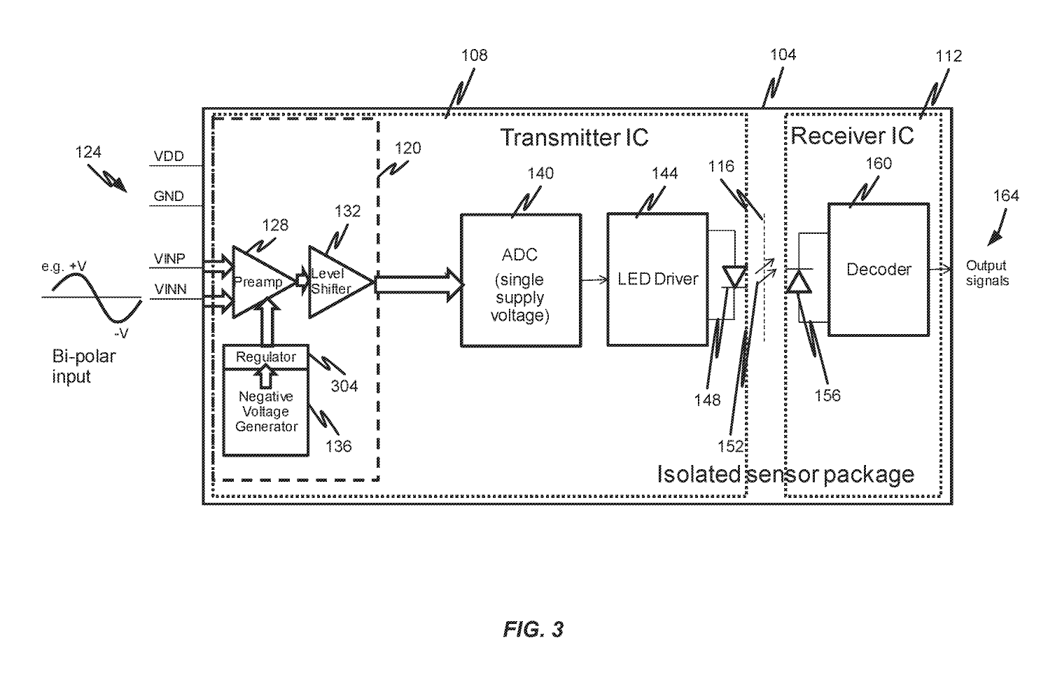

FIG. 3 shows another component that may be provided as part of the transmitter IC 108. Specifically, a regulator circuit 304 is shown to be connected between the negative voltage generator 136 and input interface circuit 128. The regulator 304 may be used to regulate the output of the negative voltage generator 136 prior to providing the output of the negative voltage generator 136 to the input interface circuit 128. More specifically, the regulator 304 may be connected to the second positive voltage provided at the supply voltage terminal VDD. The regulator 304 may also be connected with the ground voltage provided at the ground terminal GND. The regulator 304 may be provided to regulate the output of the negative voltage generator 136 to reduce the switching noise and ripples. The output of the regulator 304 may be provided to one or more supply rails of the input interface circuit 128, thereby enabling the input interface circuit 128 to sense voltages of the bi-polar input that are below the ground voltage (e.g., to enable negative voltage detection for the input interface circuit 128).

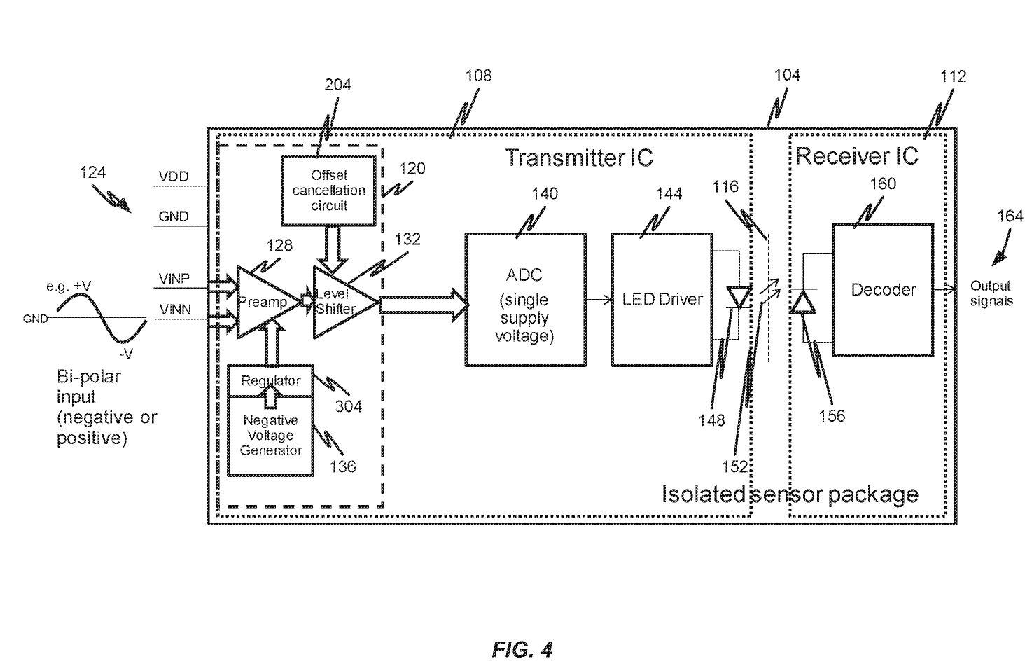

FIG. 4 depicts still another possible configuration of the isolated sensor package 104 in accordance with at least some embodiments of the present disclosure. This particular example is shown to include both the regulator 304 and the offset cancellation circuit 204 as depicted and described in connection with FIGS. 2 and 3. Thus, it should be appreciated that a transmitter IC 108 may be provided with any combination of components depicted in FIGS. 1-4 without departing from the scope of the present disclosure.

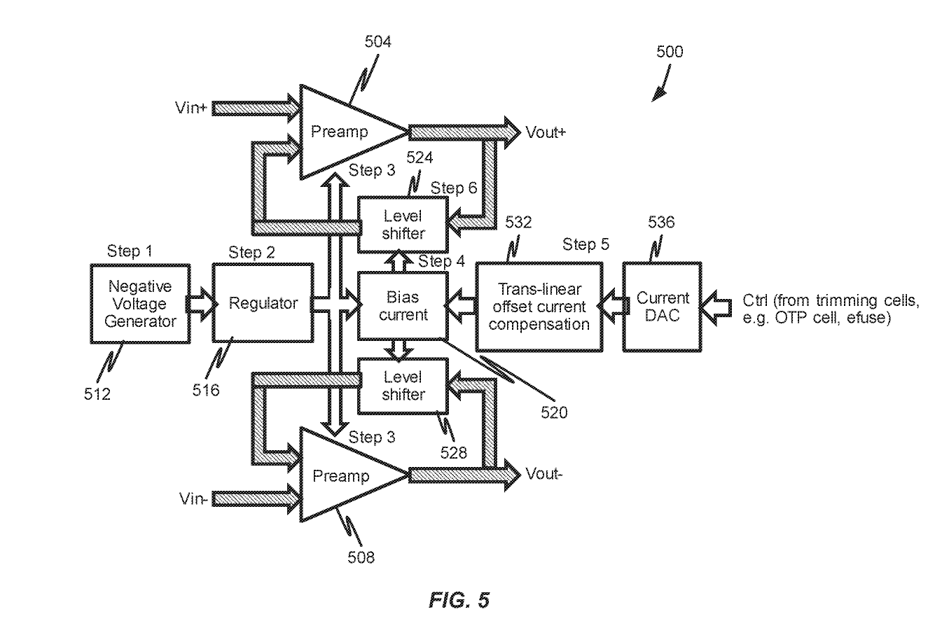

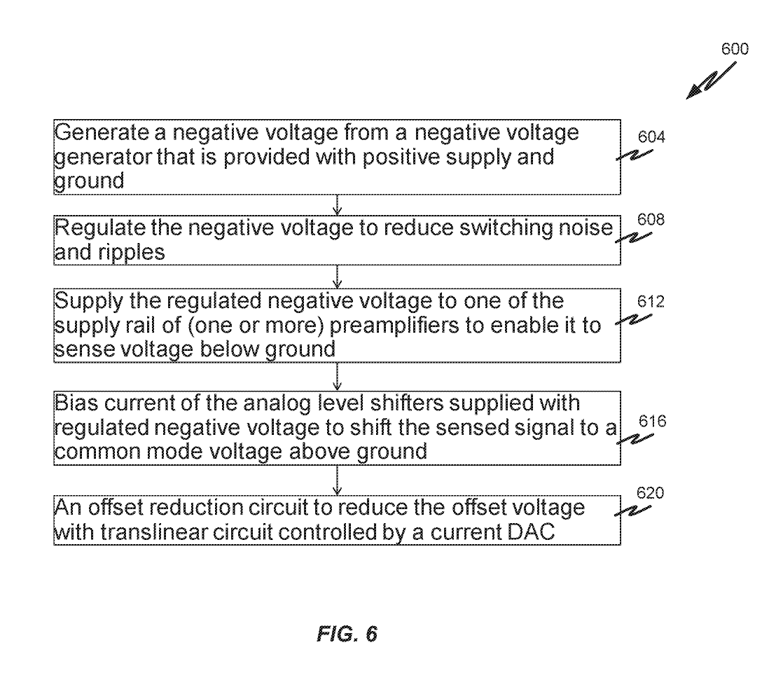

With reference now to FIGS. 5 and 6, an example set of functional circuit components 500 and their operation 600 will be described in accordance with at least some embodiments of the present disclosure. In particular, the components 500 may correspond to one, some, or all of the circuit elements depicted and described in connection with FIGS. 1-4. The components 500 may include, without limitation, a pair of preamplifiers 504, 508, a negative voltage generator 512, a regulator 516, a bias current 520, a pair of level shifters 524, 528, a translinear offset current compensation component 532, and a current Digital-to-Analog Converter (DAC) 536. The pair of preamplifiers 504, 508 may be provided as part of the input interface circuit 128. The negative voltage generator 512 may be similar or identical to the negative voltage generator 136. The regulator 516 may be similar or identical to the regulator 304. The bias current 520 and level shifters 524, 528 may be provided as part of the level shifter circuit 132. The translinear offset current compensation component 532 and current DAC 536 component may be provided as part of the offset cancellation circuit 204.

In some embodiments, the negative voltage generator 512 generates a second negative voltage (which may be less than or equal to the first negative voltage received at the negative input VINN) (step 604). The negative voltage generator 512 is capable of producing the second negative voltage even though the negative voltage generator 512 is provided with a positive voltage supply from the supply voltage terminal VDD and a ground voltage from the ground terminal GND. Thus, the negative voltage generator 512 produces the second negative voltage even though the negative voltage generator 512 is driven between a ground voltage and the second positive voltage.

The regulator 516 is used to regulate the negative voltage produced by the negative voltage generator 512 to reduce the switching noise and ripples (step 608). The creates a regulated negative voltage, which may still be at or near the second negative voltage). The regulated negative voltage is provided to one or more supply rails of the preamplifiers 504, 508 (step 612). Providing the regulated negative voltage to the preamplifiers 504, 508 enable the preamplifiers to detect any negative voltage that is present in the input signal, which is provided at the voltage inputs Vin+/Vin− (which may correspond to the input signals received at the terminals VINP/VINN, respectively). That is one of the preamplifiers 504 may be configured to receive the positive portion of the input signal whereas the other of the preamplifiers 508 may be configured to receive the negative portion of the input signal. Both preamplifiers 504, 508 may have the regulated negative voltage supplied thereto.

The outputs of each preamplifier 504, 508 may be provided to a corresponding level shifter 524, 528, respectively. The level shifters may be provided in a feedback loop of the preamplifiers 504, 508 and may be used to shift up the outputs of the preamplifiers prior to being converted into a bit stream signal by the ADC circuit 140.

A bias current 520 of the level shifters 524, 528 may be supplied with the regulated negative voltage to shift the sensed signal (provided at Vin+/Vin−) to a common mode voltage that is above the ground voltage provided at the ground terminal GND (step 616). In some embodiments, the bias current 520 is controlled by a translinear offset current compensation component 532, which receives its input from the current DAC 536. This offset may be driven or controlled by one or more trimming cells in the form of OTP cells, electrical fuses, or combinations thereof (step 620). This process 600 may be constantly performed to ensure the components 500 continue to operate in a desired manner.

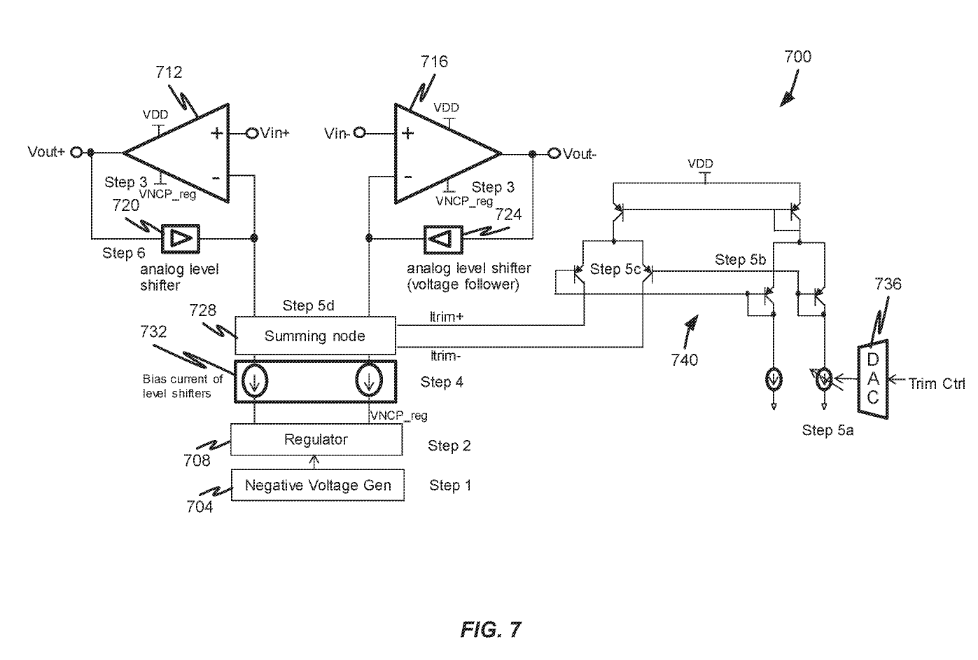

With reference now to FIG. 7, a first example offset cancellation circuit 740 provided within a larger circuit 700 will be described in accordance with at least some embodiments of the present disclosure. The circuit 700 is again shown to include similar components to other circuits depicted and described in FIGS. 1-5. For instance, circuit 700 is shown to include a negative voltage generator 704, a regulator 708, a pair of differential amplifiers 712, 716, a corresponding pair of analog level shifters 720, 724, a summing node 728, a bias current component 732, a trim control DAC 736, and the offset cancellation circuit 740.

The offset cancellation circuit 740 is shown as a low-noise offset cancellation circuit. The offset circuit 740 may be used to mitigate an offset of the two pseudo differential amplifiers 712, 716, which may be considered part of the input interface circuit 128. The summing node 728 and offset cancellation circuit 740 may be components of the offset cancellation circuit 204 and/or translinear offset current compensation component 532. Again, the negative voltage generator 704 and regulator 708 are used to produce a regulated negative voltage VNCP_reg, which is provided to the bias current component 732 as well as to the pair of differential amplifiers 712, 716. The amplifiers 712, 716 are shown to receive the input signal, which can fluctuate between positive and negative voltages, but the amplifiers 712, 716 are driven by the second positive voltage provided at the supply voltage terminal VDD and the second negative voltage in the form of the regulated negative voltage VNCP_reg. The amplifiers 712, 716 provide an output as Vout+/Vout−, which are also provided in a feedback loop to level shifters 720, 724. It should be appreciated that the level shifters 720, 724 may, in some embodiments, be provided as analog level shifters or voltage followers. The feedback loop is connected to the negative terminals of the amplifiers 712, 716 as well as the inputs of the summing node 728.

The summing node 728 also receives a trim input Itrim+/Itrim− from offset cancellation circuit 740. This input is controlled by the trim control signal provided to the DAC 736. In some embodiments, the output of the DAC 736 is provided through the offset cancellation circuit 740 to the summing node 728.

The amplifiers 712, 716 and level shifters 720, 724 may have an inherent offset to the mismatch. The Vout+ and Vout− may have a reduction in that inherent offset because the offset created by the offset cancellation circuit 740 cancels out the original offset (partially or completely). The depicted example of the offset cancellation circuit 740 is shown to have a number of transistors connected between the ground voltage and the second positive voltage provided at the supply voltage terminal VDD.

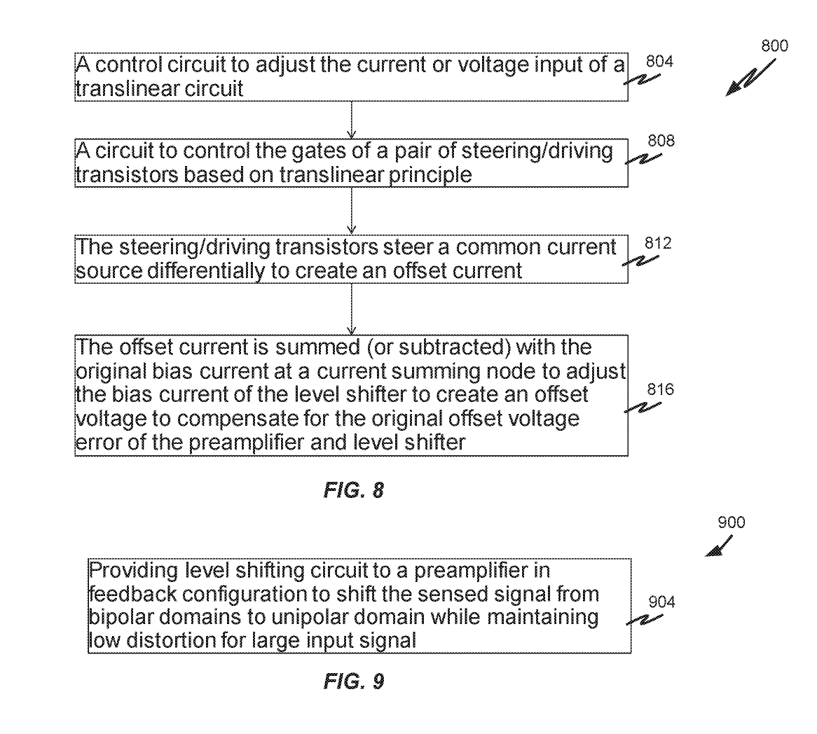

Operation of the components depicted in FIG. 7 will now be described with reference to FIG. 8. Specifically, FIG. 8 depicts a method 800 that can be used to operate the offset cancellation circuit 740 and related components, such as the summing node 728. The method 800 begins when a control circuit 736 is used to adjust the current or voltage input of a translinear circuit 740 (step 804). The translinear circuit 740 may control its various gates in a pair of steering/driving transistors based on a translinear principle (step 808). The steering/driving transistors may steer a common current source differentially to create an offset current Itrim (step 812). The offset current Itrim is summed (or subtracted) with the original bias current at a current summing node 728 to adjust the bias current of the level shifters 720, 724 (step 816). In some embodiments, the creates an offset voltage to compensate for the original offset voltage error of the preamplifiers 712, 716 and the level shifters 720, 724.

With reference now to FIG. 9, an additional method 900 of operating a level shifter 132 or level-shifting circuit will be described in accordance with at least some embodiments of the present disclosure. The method 900 includes a step of providing a level shifting circuit (e.g., level shifter 132 and/or level shifters 720, 724) to a preamplifier (e.g., the input interface circuit 128 and/or amplifiers 712, 716). The level shifting circuit(s) may be provided in a feedback configuration to help shift a signal sensed at the amplifiers (e.g., bi-polar input and/or Vin+/Vin−) from a bi-polar domain to a unipolar domain (step 904). This shifting from the bi-polar domain to the unipolar domain may be done while maintaining a relatively low distortion for a large input signal.

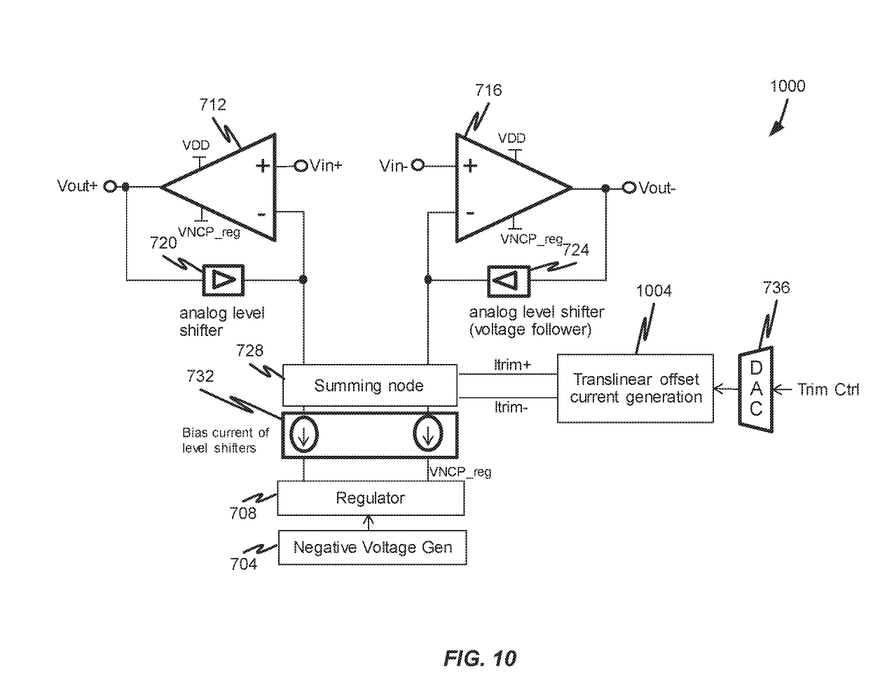

FIG. 10 depicts another circuit 1000 in accordance with at least some embodiments of the present disclosure. Circuit 1000 is similar to circuit 700, except that the translinear circuit 740 is shown more generically as a translinear offset current generation block 1004. This translinear offset current generation block 1004 and the summing node 728 may collectively form the offset cancellation circuit 204 and may help to reduce or mitigate the offset inherent between the amplifiers 712, 716 and level shifters 720, 724.

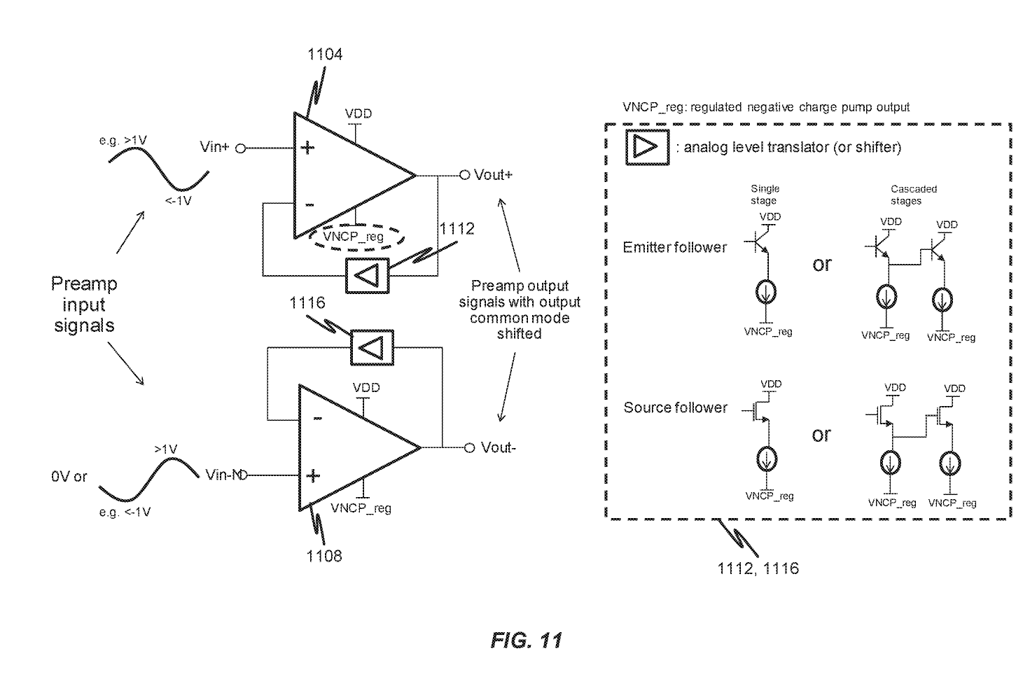

FIG. 11 depicts additional details of the input interface circuit 128 and level shifter 132 provided in a feedback configuration in accordance with at least some embodiments of the present disclosure. Specifically, the pair of amplifiers 1104, 1108 may be similar or identical to amplifiers 712, 716 and the level shifters 1112, 1116 may be similar or identical to level shifters 720, 724.

A typical voltage sensor is usually configured to have high input impedance as they are typically placed in parallel with the signal path. With high input impedance, the signal path is not disturbed by the sensor. In some embodiments, the large input impedance is implemented by adopting a unity gain buffer configuration. The unity gain buffer configuration facilitates a high input impedance as the positive and negative terminals are always on the same potential and bias current of the input pairs are always constant. So even for bi-polar input pairs, the base current is substantially constant regardless of the signal swing.

An analog-level translator (or shifter) 1112, 1116 or voltage follower is used as the feedback element to shift the output DC level to a positive reference voltage so that there will be no clipping of the output voltage with enough headroom. As the vbe (base-to-emitter voltage) is typically 0.7V or vth (threshold voltage) is typically 1V, a series of level shifters may be required to shift the output voltage up. The feedback also improves the linearity and total harmonic distortion of the output signal.

As the preamplifiers 1104, 1108 sometimes need to have an input range much lower than ground, the lower rail of each preamplifier 1104, 1108 is supplied with an integrated negative charge pump with regulation, as denoted by VNCP_reg. The negative supply voltage attempts to guarantee the headroom for the input signal range. The regulation on the output of the charge pump is useful to reduce the disturbance of the switching supply noise and ripples to the preamplifiers 1104, 1108. This is helpful as the preamplifier is the first stage of the sensor and it affects the system SNR) with no gain reduction. Again, the transistors provided in an emitter follower or source follower configuration for the level shifters 1112, 1116 may correspond to a single stage or cascaded stages.

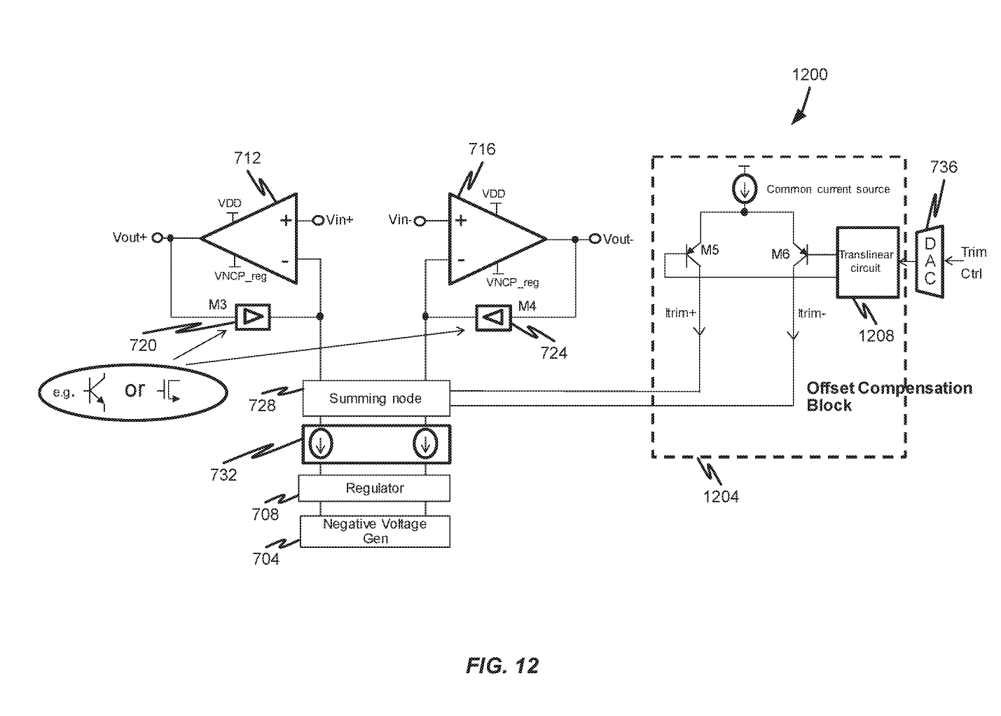

With reference now to FIG. 12, yet another circuit 1200 will be described in accordance with at least some embodiments of the present disclosure. The circuit 1200 is similar to circuit 700, except that the offset cancellation circuit 740 is replaced with an offset compensation block 1204 and additional, non-limiting, details of the level shifters 720, 724 are shown. Specifically, the offset compensation block 1204 is shown to include a pair of transistors M5, M6, which are both connected to a translinear circuit and a common current source. The transistors M5, M6 provide trimming currents as an output, which are each provided to the summing node 728. Again, the input of the offset compensation block 1204 is the output of the DAC 736. In some embodiments, the noise from the common current source will be common to Vout+ and Vout−, this its effects will be cancelled. As can be appreciated by one of skill in the art, the transistors M5, M6 can be Bipolar Junction Transistors (BJTs) or CMOS transistors.

Similarly, the level shifters 720, 724 may correspond to one or multiple transistors M3, M4. The transistors M3, M4 can be provided as voltage follower transistors and can be a single transistor or a series of level-shifting transistors. In some embodiments, the effective current to the voltage follower transistor M3 is approximately the source current (Is) minus Itrim+ and the effective current to the voltage follower transistor M4 is approximately Is minus Itrim−. This means that the current difference between M3 and M4 is equal to the different between the positive and negative current trim values. The current sources of the voltage follower transistors are two matched current sources. The trimming currents are added at the source of the cascade transistors M3, M4, which results in the summing node 728 having a rather constant voltage when the input voltage changes.

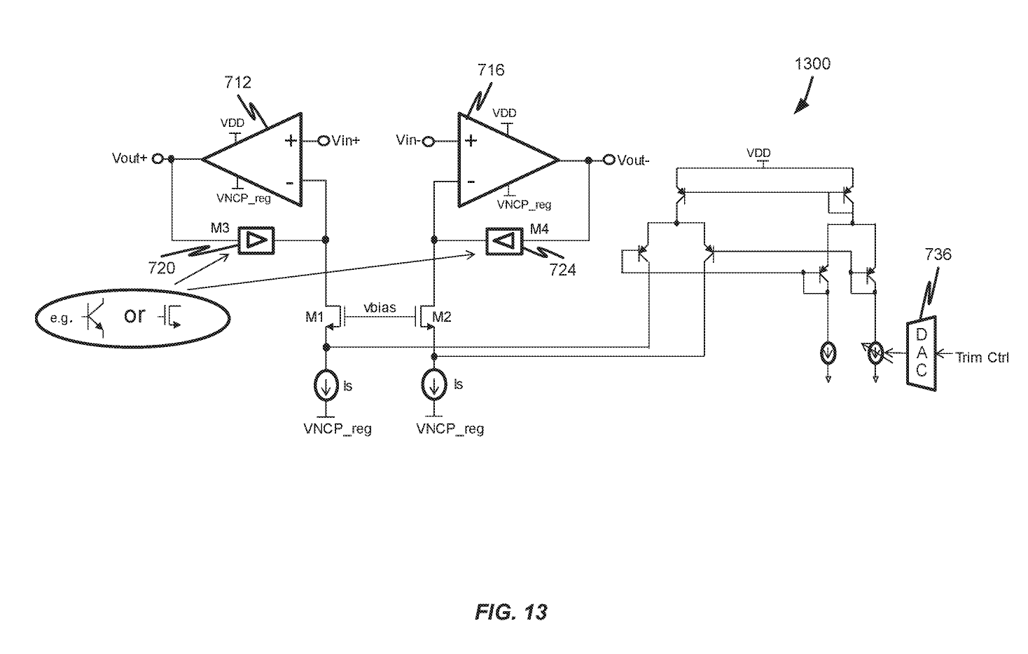

FIG. 13 depicts another variant circuit 1300, which is similar to circuit 1200 and/or circuit 700. The details of circuit 1300 show the particular connection between offset compensation block and the summing node, which is illustrated as a pair of transistors M1, M2. The first transistor M1 may be connected to the feedback loop of the amplifier 712 and level shifter 720. The second transistor M2 may be connected to the feedback loop of the other amplifier 716 and the other level shifter 724. The transistors M1, M2 are biased with a fixed voltage, vbias at their gates. The source of each transistor M1, M2 is shown to be connected to the output of the offset compensation block 1204 to create a low impedance summing node at the sources of the transistors M1, M2.

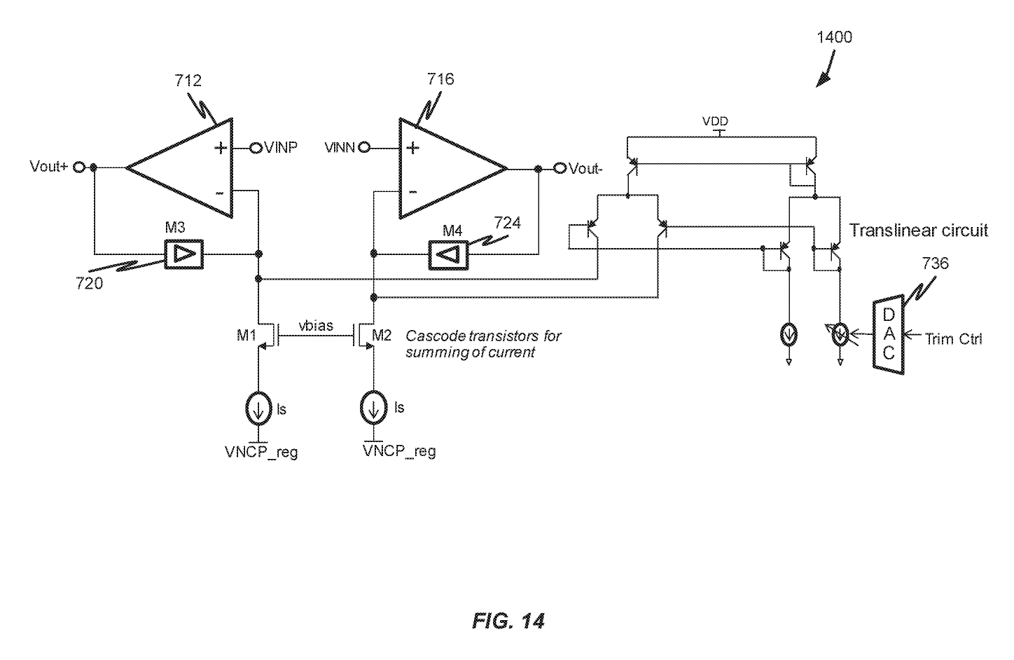

FIG. 14 depicts an alternative configuration where the output of the offset compensation block 1204 is provided at the drain of the transistors M1, M2. The current sources of the voltage followers/level shifters can also be two matched sources in this particular embodiment. For instance, the matched current sources are placed close together in layout so that their IV characteristics closely resemble one another, thereby producing a low offset and noise at the output. The trimming currents (e.g., outputs of the offset compensation block 1204) are added at the drains of the transistors M1, M2. In this example, the summing node is subjected to the input voltage swings and may produce a channel length modulation effect to the current sources.

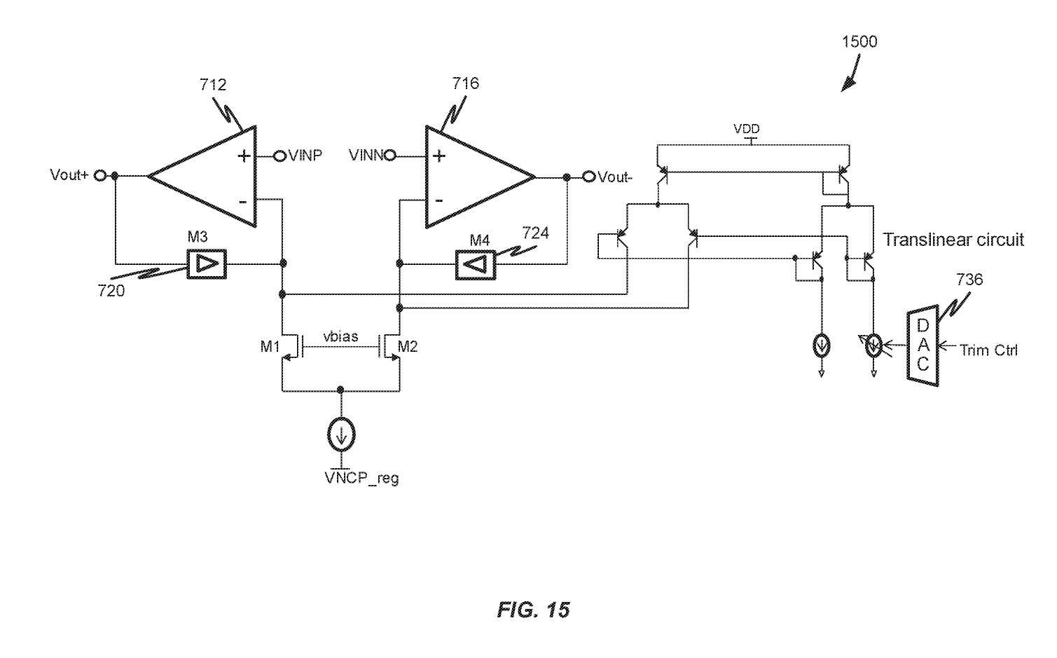

FIG. 15 depicts still another alternative configuration for system 1500. In this configuration, the system 1500 is shown to include two matched current sources that are merged to a single current source to reduce the noise effect, as the uncorrelated noise from the two matched current sources become common noise to the differential outputs of the interfacing circuit. Thus, the noise effect is cancelled out as Vout=Vout+−Vout−. However, the current may not split equally to the two level shifters 720, 724 as it is subjected to the process mismatch of the two transistors M1 and M2, which will then result in offset.

Actual semiconductor devices may exhibit mismatches in implementation. This mismatches can be caused by any number of variables (e.g. random process variations during fabrication such as dimensions, dopings, oxide thickness, mechanical stresses, temperature gradients, etc.). These mismatches result in offset voltage at the output, that is the output voltage is not zero with zero input voltage. Offset voltage impacts the accuracy of the sensed voltage. For a system that requires high precision, a few millivolts of offset voltage may not be tolerable. Therefore, the input interface circuit 128 should aim to achieve very low offset voltage by matching in layout, some circuit technique such as chopper stabilization, or post-fabrication trimming.

There could be multiple source of errors in the previous two single-ended unity-gain amplifiers 712, 716, such as the offset of the two opamps (e.g. process mismatch in the input pairs or current mirrors in the opamps, systematic offset due to inherent limited gain of the opamps), vbe (base-to-emitter voltage) and beta mismatch of the emitter followers (or the threshold voltage mismatches in the source followers), and/or current sources mismatch of the voltage followers.

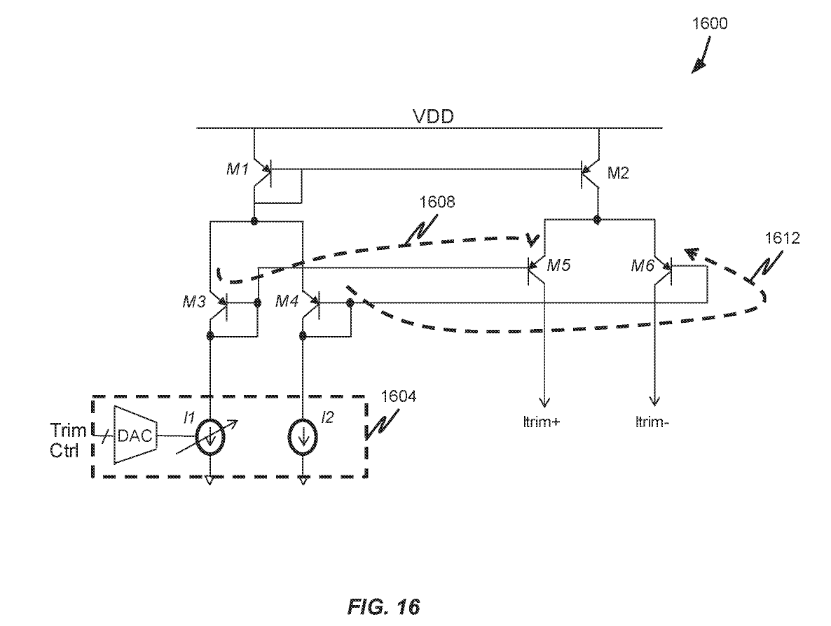

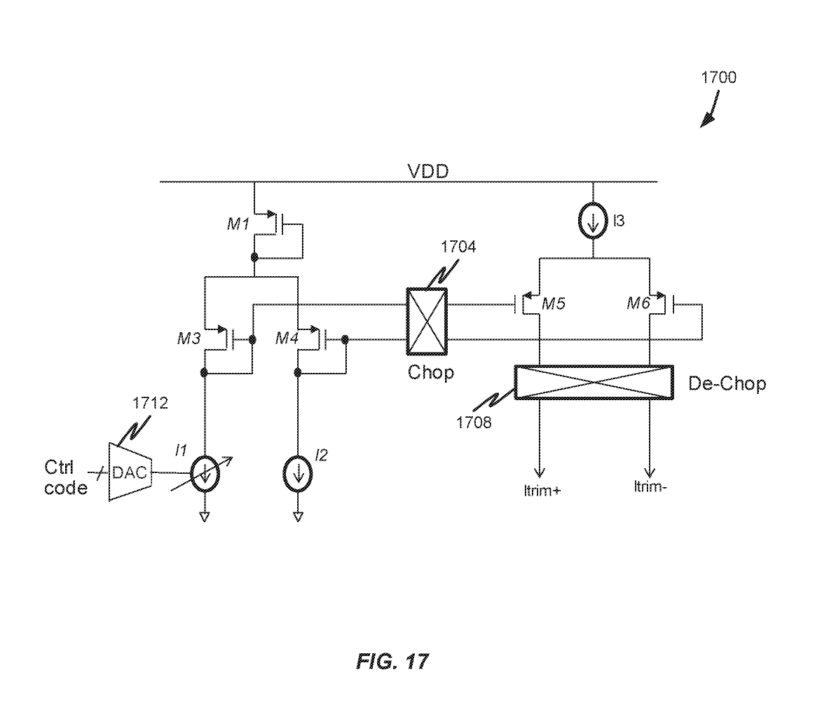

With reference now to FIG. 16, an illustrative translinear offset cancellation circuit 1600 using BJT devices M1-M6 will be described in accordance with at least some embodiments of the present disclosure. A linear circuit typically eases its control. Lesser time is required for trimming as the trimming code can be easily calculated according to simple linear equations. Circuit 1600 shows how the trimming of the differential current output can be controlled by using a translinear loop formed by the devices M3, M4, M5 and M6. The translinear loop is linear, i.e. sum of vbe (base-emitter voltage) of the transistors in clockwise direction 1608 is equal to sum of vbe of the transistors in anti-clockwise direction 1612. Therefore, the differential current output can be tuned by a single current source I1. The tuning of I1 can be set by switching on or off a series of current mirrors, or by tuning resistors which convert voltage to current (shown in FIG. 17 as part of circuit 1700). Transistors M5 and M6 may be provided to steer the common current source 13 differentially as Itrim+ and Itrim−. The noise of the common current source will be cancelled out at the differential output. The other current source I2 is a reference current branch to bias the gate of transistor M6. The current I1 is substantially programmable with the help of control circuit 1604, which is shown to include a programmable current I1 from a current DAC.

As seen in FIG. 17, the circuit 1600 may be modified to result in circuit 1700. Circuit 1700 is shown to have transistors M1-M6 realized as CMOS transistors rather than BJT devices. When using CMOS devices, the translinear principle is an approximation to that of using BJT devices. Again, circuit 1700 shows the trimming of the differential current output Itrim+/Itrim−, which is controlled by using a translinear loop that includes the transistors M3, M4, M5, M6. This translinear loop follows a sum of square root principle (e.g., sum of square root (current/(W/L)) of the transistors in clockwise direction is equal to sum of square root (current/(W/L)) of the transistors in anti-clockwise direction). Therefore, the differential current output can be tuned by a single current source I1, which is programmable from a current DAC 1712 (which may be similar or identical to other DACs depicted and described herein). The tuning of I1 can be set by switching on or off a series of current mirrors, or by tuning resistors which convert voltage to current. M5 and M6 steer the common current source 13 differentially as Itrim+ and Itrim−. The noise of the common current source will be cancelled out at the differential output. I2 is a reference current branch to bias the gate of M6.

A chopper technique can be used to reduce flicker noise of the CMOS devices by adding chopper switches 1704 at the gate of M5 and M6, and demodulation switches 1708 at the drain of M5 and M6. The low frequency flicker noise of M5 and M6 are also reduced by the chopping technique as it is moved to higher frequency (out of the frequency band of interest) and can be filtered out. The chop and de-chop logic may correspond to cross-coupled switches as is known in the art.

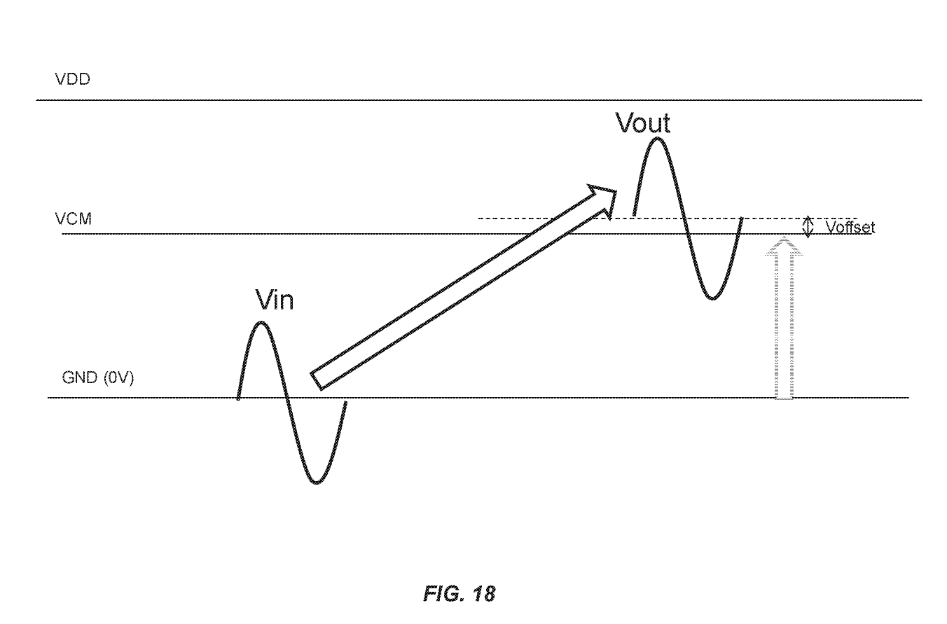

FIG. 18 depicts the waveforms input to the input interface circuit 128 and then output by the level shifter 132 in accordance with at least some embodiments of the present disclosure. In particular, the input signal Vin is provided as an example of the bi-polar input at the input terminals VINP, VINN. The bi-polar input signal is level shifted to a common mode voltage (VCM) above ground after the level shifter 132 (or other level shifters depicted and described herein). The mismatches of the devices of the input interface circuit 128 and level shifters 132 due to process fabrication generating random offset voltage Voffset, adversely impact the accuracy of a voltage sensor using the isolated sensor package 104. The offset voltage Voffset may also vary with temperature (e.g., there is a possibility of temperature drift).

When changing the trimming control code (e.g., by the value n) the difference of the two trimming currents, delta Itrim (e.g., Itrim+−Itrim−), is changed linearly based on translinear principle, Delta Itrim=k*n, where k is constant. From the circuit 1200, 1300, 1400, 1500, 1600 or 1700 with level shifter and emitter follower, the delta Voffset generated by the offset compensation block is proportional to ln(l+k*n). When k is small (e.g., the trimming current step is small compared to bias current), by Taylor series expansion y=kx is obtained, i.e. delta Voffset is proportional to n.

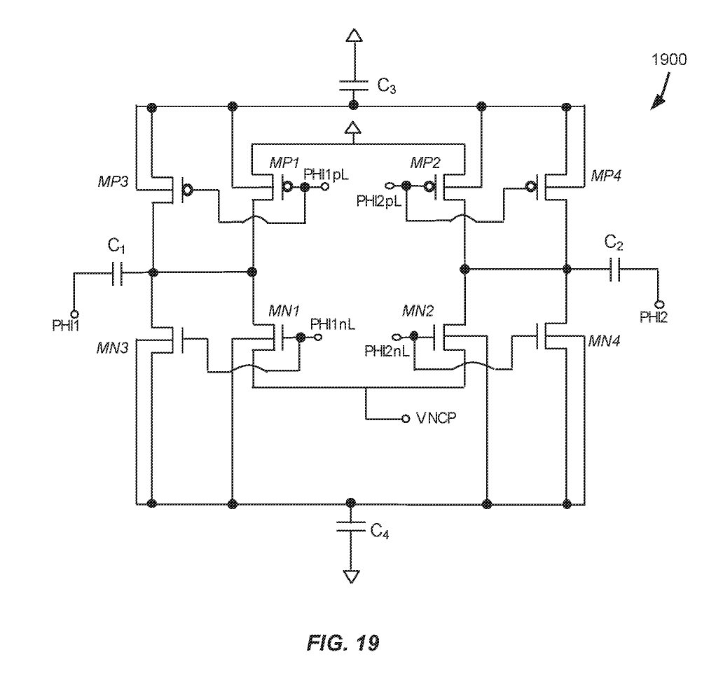

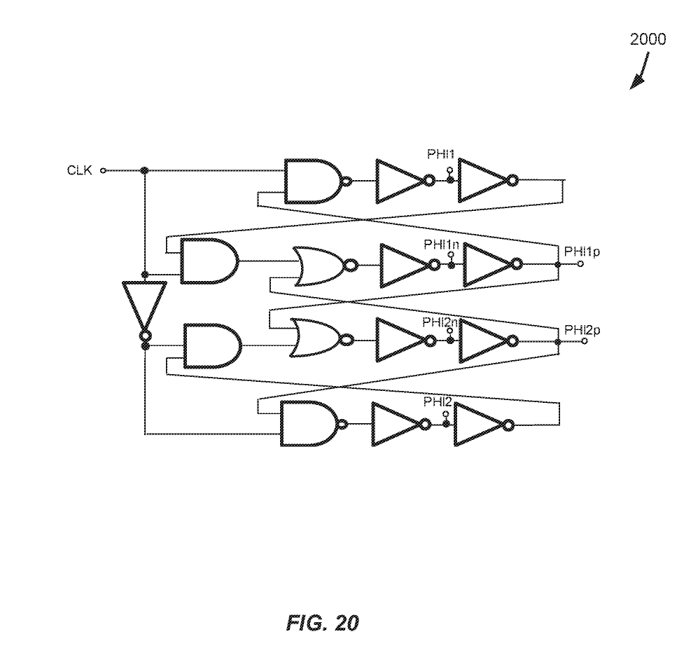

A negative charge pump 1900 as shown in FIG. 19 may be designed to realize the negative supply of the amplifiers and level shifters. No passive devices such as diodes and resistors are used in the circuit 1900 to achieve a desirable high efficiency. The control signals such as PHI1 and PHI2, PHI1pL and PHI2pL, and PHI1nL and PHI2nL are non-overlapping clocks 2000 as shown in FIG. 20 to prevent reverse leakage current or shoot-through current. MP1, MP2, MN1 and MN2 are the main transistors in the charge pump 1900. On one phase when the PHI1 clock is high, the terminal of C1 (connecting with MP1 and MN1) is connected to ground through MP1. On the other phase when PHI1 clock is low, the terminal of C1 is connected the output VNCP and the charge is transferred over to the load. C2 operation is the reversed of C1 during the same phase.

By synchronizing the control signals and with the non-overlapping time (dead-band), the charge pump 1900 is able to reduce shoot-through and reverse leakage current to achieve high efficiency.

The pwell of the NMOS transistors MN1 and MN2 (in a triple-well process) may need to be biased to the lower potential of the source and drain terminal such that no parasitic devices are turned on. MN3 and MN4 are added to bias the well of MN1 and MN2 during the different clock phases. C4 holds the voltage during the dead-time of the non-overlapping clock. Similarly, MP3 and MP4 bias the nwell of MP1 and MP2 together with C3 that holds the voltage during dead-time. This is to prevent latch-up so that the pn junction between substrate and nwell of the PMOS will not be turned on.

The different clock phases can be generated with a non-overlapping clock generation circuit. The sequence of the non-overlapping clock phases is: PHI1 goes low->PHI1nL goes high->PHI2nL goes low->PHI2 goes high.

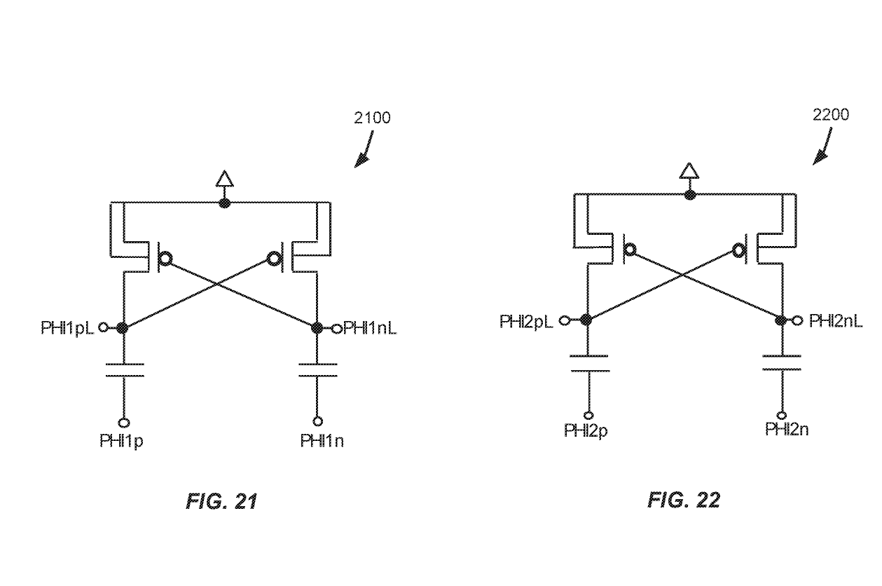

The phases PHI1n and PHI1p are shifted to PHI1nL and PHI1pL, respectively with auxiliary charge pumps 2100 as shown in FIG. 21. A similar or identical circuit 2200 may also be used for generating phases PHI2nL and PHI2pL as shown in FIG. 22.

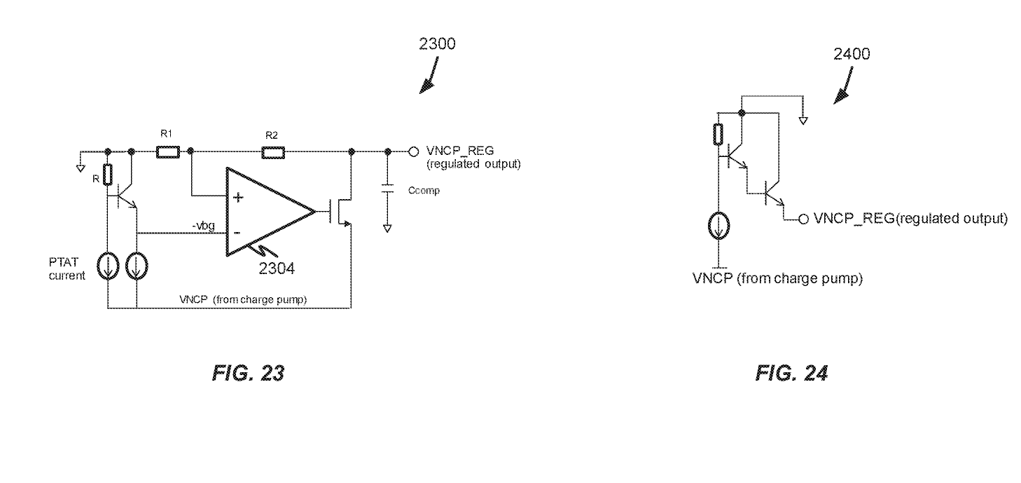

To achieve a high SNR for the preamplifier input interface circuit 128, the output voltage from the negative charge pump 1900 may further be regulated by a Low-Drop-Out (LDO) regulator 2300 or shunt clamp 2400 to produce the desired output voltage. Examples of an LDO regulator and shunt clamp 2400 are shown in FIGS. 23 and 24, respectively. The Ccomp serves as a compensation capacitor to stabilize the LDO regulator 2300. It also filters the output ripples and noise from the charge pump 1900. The reference voltage, −vbg (inverse bandgap voltage) can be generated by mirroring a PTAT (proportional-to-absolute-temperature) current through a resistor, R and combined with a vbe (which has a negative temperature coefficient) of a bipolar transistor to produce a temperature-insensitive reference voltage. R1 and R2 form a voltage divider to obtain the desired negative voltage for regulator output, VNCP_reg.

Another method to produce a regulated voltage is to place a shunt or clamp circuit 2400 at the output of the negative charge pump 1900. The output voltage is equal to the sum of IR drop and vbe (can be sum of multiple vbe) below ground.

As can be appreciated, any of the components/devices depicted and described herein may be implemented as on-chip solutions (e.g., as a single silicon wafer). In some embodiments, the isolators may be implemented in an Integrated Circuit (IC) chip having other circuit elements provided therein. Moreover, the terms isolator, isolation device, isolated sensor package, and isolation system may be interchangeable terms as used herein.

Specific details were given in the description to provide a thorough understanding of the embodiments. However, it will be understood by one of ordinary skill in the art that the embodiments may be practiced without these specific details. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art.

What is claimed is:

1. An isolation device for isolating a first circuit from a second circuit, the isolation device comprising:
an input interface circuit configured to receive an input signal from the first circuit to produce a first output signal, wherein the input signal ranges between a first negative voltage and a first positive voltage;
a supply voltage terminal configured to provide a second positive voltage;
a ground terminal configured to provide a ground voltage;
a negative voltage generator configured to generate a second negative voltage for the input interface circuit;
a level shifter configured to shift the first output signal into a second output signal having a voltage level between the ground voltage and the second positive voltage;
an analog-to-digital circuit configured to convert the second output signal into a bit stream signal;
an emitter configured to convert the bit stream signal into an optical signal;
a detector configured to receive the optical signal and then generate a reproduced signal based on the received optical signal; and
an isolation boundary positioned between the detector and the emitter thereby providing the isolation between the first circuit and the second circuit, wherein the ground voltage and the second positive voltage are fed to the level shifter, the analog-to-digital circuit, and the emitter.

2. The isolation device of claim 1, wherein:
the level shifter comprises a first level shift circuit; and
the input interface circuit comprises a first amplifier having first differential input terminals and an output terminal, and wherein the first level shift circuit is coupled between the output terminal and one of the first differential input terminals.

3. The isolation device of claim 2, wherein:
the level shifter comprises a second level shift circuit; and
the input interface circuit comprises a second amplifier having second differential input terminals and an output terminal, and wherein the second level shift circuit is coupled between the output terminal and one of the second differential input terminals.

4. The isolation device of claim 3, further comprising a compensation circuit configured to receive a compensation control signal that comprises a component indicative of an offset voltage of the input interface circuit.

5. The isolation device of claim 4, further comprising a summing circuit configured to generate a biasing control signal to the level shifter in response to the second output signal and the compensation control signal.

6. The isolation device of claim 1, wherein the second positive voltage is greater than the first positive voltage.

7. The isolation device of claim 1, wherein the second negative voltage is larger in magnitude than the first negative voltage.

8. The isolation device of claim 1, wherein the second negative voltage and the first negative voltage are approximately equal to one another.

9. The isolation device of claim 1, further comprising a driver circuit for the emitter that receives the bit stream signal and drives the emitter to produce the optical signal based on the bit stream signal, wherein the driver circuit is connected to the ground voltage and the second positive voltage.

10. The isolation device of claim 1, further comprising a regulator circuit positioned between the negative voltage generator and the input interface circuit, wherein the regulator is connected to the second positive voltage.

11. The isolation device of claim 1, wherein an output of the level shifter is connected directly to an input of the analog-to-digital circuit and wherein an input of the level shifter is connected directly to an output of the input interface circuit.

12. The isolation device of claim 1, further comprising an offset cancellation circuit connected to the level shifter and configured to mitigate an offset between the input interface circuit and the level shifter, wherein the offset cancellation circuit comprises a one-time programmable cell.

13. An isolation sensor package, comprising:
a first input signal terminal;
a second input signal terminal;
a voltage supply terminal;
a ground terminal;
an output terminal;
a first Integrated Circuit (IC) chip, including:
an input interface circuit that receives an input signal from the first input signal terminal and the second input signal terminal, wherein the input signal ranges between a first positive voltage and a first negative voltage;
a negative voltage generator that generates a second negative voltage;
a level shifter that receives an output of the input interface circuit and based on the received output, generates a modified signal having a voltage level between a ground voltage provided to the ground terminal and a second positive voltage that is present at the voltage supply terminal; and
an emitter configured to produce a coupling signal based, at least in part, on the modified signal generated by the level shifter;
a second IC chip, including:
a detector configured to receive the coupling signal and convert the coupling signal into an output signal for transmission on the output terminal; and
an isolation boundary that electrically isolates the first IC chip from the second IC chip but allows the coupling signal to pass therethrough.

14. The isolation sensor package of claim 13, wherein the first IC chip further comprises an analog-to-digital conversion circuit that converts the modified signal generated by the level shifter into a bit stream that is provided to the emitter.

15. The isolation sensor package of claim 14, wherein the level shifter is coupled to the ground voltage and the second positive voltage.

16. The isolation sensor package of claim 15, wherein the analog-to-digital conversion circuit and the emitter are also coupled to the ground voltage and the second positive voltage and wherein the second positive voltage is greater than the first positive voltage.

17. The isolation sensor package of claim 15, wherein the second negative voltage is less than or equal to the first negative voltage.

18. The isolation sensor package of claim 15, wherein the input interface circuit comprises at least one amplifier having differential input terminals and an output terminal and wherein the level shift circuit is coupled between the output terminal of the at least one amplifier and the analog-to-digital conversion circuit.

19. The isolation sensor package of claim 15, wherein the first IC chip further comprises a compensation circuit that receives a compensation control signal having a component indicative of an offset voltage of the input interface circuit.

20. A method of communicating an input signal that ranges between a first positive voltage and a first negative voltage in a first circuit to a second circuit that is electrically isolated from the first circuit, the method comprising:
generating a second negative voltage from a negative voltage generator that is provided as part of a first Integrated Circuit (IC), wherein the negative voltage generator is provided with a second positive voltage and a ground voltage;
providing the second negative voltage to an input interface circuit;
providing the input signal to the input interface circuit;
enabling the input interface circuit to produce a first output based on the input signal and the second negative voltage;
level shifting the first output to a common mode voltage that is above ground;
converting the level shifted output into an optical signal; and
transmitting the optical signal across an isolation boundary that electrically isolates the first circuit from the second circuit.
